(19) United States
(12) Patent Application Publication
(10) Pub. No.: US 2026/0068053 A1
(43) Pub. Date: Mar. 5, 2026

(54) MAGNETIC ELECTRONIC COMPONENT AND HAND-MADE CIRCUIT KIT

(71) Applicant: Aidmics Biotechnology Co., Ltd., TAIPEI CITY (TW)

(72) Inventors: Chang-Ching YEH, TAIPEI CITY (TW); Chang-Yu CHEN, TAIPEI CITY (TW); Shu-Sheng LIN, TAIPEI CITY (TW)

(21) Appl. No.: 19/320,149

(22) Filed: Sep. 5, 2025

(30) Foreign Application Priority Data
Sep. 5, 2024 (TW) 113133597

(51) Int. Cl. H05K 1/18

(52) U.S. Cl. CPC H05K 1/18; H05K 2201/08; H05K 2201/10954

(57) ABSTRACT

A magnetic electronic component includes a circuit board, a functional part, at least one magnet and at least one conductive fixing member. The circuit board has a circuit pattern. The functional part is arranged on the circuit board and are electrically connected to the circuit pattern. The magnet is located at one side of the circuit board. The conductive fixing member is configured to electrically connect the circuit pattern of the circuit board and fix the magnet.

### CROSS REFERENCE TO RELATED APPLICATIONS

This Non-provisional application claims priority under 35 U.S.C. § 119(a) on Patent Application No(s). 113133597 filed in Taiwan, Republic of China on Sep. 5, 2024, the entire contents of which are hereby incorporated by reference.

### BACKGROUND

### Technology Field

This disclosure relates to an electronic component and, in particular, to a magnetic electronic component and a hand-made circuit kit with the magnetic electronic component.

### Description of Related Art

Printed electronics is an emerging technology with potential applications in photovoltaics, transistors, displays, batteries, antennas, and sensors. In recent years, electronic circuit products based on paper substrates have been presented on the market. These paper substrates have the advantages of low cost, flexibility, lightweight, and disposable.

U.S. Pat. No. 9,401,239 discloses an electrical component 100 (as shown in FIG. 1) that can be attached to a paper substrate 114 or other substrate 116 (e.g., a metal plate). The electrical component 100 can be quickly and easily attached to conductive lines 120 on the paper substrate 114 using magnetic attraction to construct simple or complex circuits. This product is suitable for various applications such as engineering and education. As shown in FIG. 1, the electrical component 100 includes a circuit board 102, two support pillars 104, and a functional part 124. The functional part 124 is disposed on the upper surface 102a of the circuit board 102, and the two support pillars 104 are disposed on the lower surface 102b of the circuit board 102. Each support pillar 104 includes a channel 106 extending from the top opening to the bottom opening. A magnet 108 is movably positioned in the channel 106 and electrically connected to the circuit board 102. The width of the bottom opening of the channel 106 is less than the maximum lateral dimension of the magnet 108. An electrically conductive spring 112 is further disposed in the channel 106, and is configured to movably position the magnet 108 in the channel 106, and enable the magnet 108 to be electrically connected to the circuit board 102.

However, in order to secure the support pillars 104 to the circuit board 102, multiple through holes must be formed in the circuit board 102 in advance. The multiple legs of the support pillars 104, which are made of plastic material, are then passed through these through holes. A heat process is then used to melt the parts of the legs extending beyond the through holes so as to form the welded portions 104a. This conventional design not only requires the use of multiple small parts but also requires multiple different manufacturing processes, making it quite complex and time-consuming.

Therefore, it is desired to provide a magnetic electronic component that has a simple structure design and can be easily manufactured with a lower manufacturing cost.

### SUMMARY

In view of the foregoing, an objective of this disclosure is to provide a magnetic electronic component that has a simple structure design, so that it can be easily manufactured and have a lower manufacturing cost.

A magnetic electronic component of this disclosure includes a circuit board, a functional part, at least one magnet, and at least one conductive fixing member. The circuit board has a circuit pattern. The functional part is arranged on the circuit board and electrically connected to the circuit pattern. The magnet is located at one side of the circuit board. The conductive fixing member is configured to electrically connect the circuit pattern of the circuit board and fix the magnet.

In one embodiment, the conductive fixing member includes a main body and at least two connecting legs, and the magnet is disposed between the circuit board and the main body. Each of the connecting legs connects the main body and the circuit board and located adjacent to the magnet, so that the magnet can be limited between the main body, the connecting legs and the circuit board. At least one of the connecting legs is electrically connected to the circuit pattern of the circuit board.

In one embodiment, the main body has a contact portion for pressing the magnet, so that the magnet can be fixed between the main body, the connecting legs and the circuit board.

In one embodiment, the conductive fixing member further includes a limiting flange, one end of the limiting flange is connected to the main body, another end of the limiting flange is a free end, and the limiting flange is located adjacent to the magnet, so that the magnet is restricted between the main body, the connecting legs, the limiting flange and the circuit board.

In one embodiment, at least one of the connecting legs is electrically connected to the circuit pattern by welding.

In one embodiment, the circuit board is a printed circuit board, and the circuit pattern includes at least one conductive line formed on the printed circuit board.

In one embodiment, the circuit board is a plate structure having a shape of circle, triangle, rectangle, or polygon.

In one embodiment, the functional part is electrically connected to the conductive fixing member through the circuit pattern.

In one embodiment, the functional part includes a passive part, an active part, a power supply part, a switch part, and/or a conductive part.

In one embodiment, the functional part includes a light-emitting diode, a buzzer, a speaker, a motor, a fan, a color change plate, a heater, and/or an electromagnet.

In one embodiment, the magnetic electronic component includes two magnets and two conductive fixing members, the two conductive fixing members are electrically connected to the circuit pattern of the circuit board and fix the two magnets, respectively.

In one embodiment, the magnetic electronic component further includes a battery and a power fixing member. The battery is electrically connected to the circuit pattern of the circuit board for providing a driving power to the functional part. The power fixing member is configured to electrically connect the circuit pattern of the circuit board and fix the battery.

A hand-made circuit kit of this disclosure includes a mounting plate, a circuit pattern module, and at least one magnetic electronic component. The circuit pattern module is arranged on the mounting plate, and the circuit pattern module includes at least one circuit line pattern. The magnetic electronic component is detachably and movably arranged on the circuit pattern module and magnetically attached on the mounting plate, so that the circuit pattern module is located between the magnetic electronic component and the mounting plate. The magnetic electronic component includes a circuit board, a functional part, at least one magnet, and at least one conductive fixing member. The circuit board has a circuit pattern. The functional part is arranged on the circuit board and electrically connected to the circuit pattern. The magnet is located at one side of the circuit board. The conductive fixing member is configured to electrically connect the circuit pattern of the circuit board and fix the magnet. When the magnetic electronic component is arranged on the circuit pattern module, the magnet is magnetically attached on the mounting plate, and the conductive fixing member contacts the circuit line pattern.

In one embodiment, the conductive fixing member includes a main body and at least two connecting legs, and the magnet is disposed between the circuit board and the main body. Each of the connecting legs connects the main body and the circuit board and located adjacent to the magnet, so that the magnet can be limited between the main body, the connecting legs and the circuit board, and at least one of the connecting legs is electrically connected to the circuit pattern of the circuit board.

In one embodiment, the main body has a contact portion for pressing the magnet, so that the magnet can be fixed between the main body, the connecting legs and the circuit board.

In one embodiment, the conductive fixing member further includes a limiting flange, one end of the limiting flange is connected to the main body, another end of the limiting flange is a free end, and the limiting flange is located adjacent to the magnet, so that the magnet is restricted between the main body, the connecting legs, the limiting flange and the circuit board.

In one embodiment, at least one of the connecting legs is electrically connected to the circuit pattern by welding.

In one embodiment, the functional part is electrically connected to the conductive fixing member through the circuit pattern.

In one embodiment, the circuit pattern module further includes a substrate, and the circuit line pattern is arranged on the substrate.

In one embodiment, the circuit line pattern is formed by at least one of a conductive sticker, a conductive ink, a conductive paste, and a conductive paper.

In one embodiment, the magnetic electronic component further includes a battery and a power fixing member. The battery is electrically connected to the circuit pattern of the circuit board for providing a driving power to the functional part. The power fixing member is configured to electrically connect the circuit pattern of the circuit board and fix the battery. When the magnetic electronic component is arranged on the circuit pattern module, the power fixing member contacts the circuit line pattern.

A manufacturing method of a magnetic electronic component includes the following steps of: providing a circuit board, wherein the circuit board has a circuit pattern; arranging a functional part on the circuit board and electrically connecting the functional part to the circuit pattern; connecting at least one conductive fixing member to the circuit board, so that the conductive fixing member is electrically connected to the circuit pattern of the circuit board; disposing at least one magnet between the conductive fixing member and the circuit board; and processing the conductive fixing member to fix the magnet between the conductive fixing member and the circuit board.

In one embodiment, the conductive fixing member includes a main body and at least two connecting legs, the magnet is disposed between the circuit board and the main body, and the step of connecting at least one conductive fixing member to the circuit board includes: connecting the connecting legs to the circuit board, and electrically connecting at least one of the connecting legs to the circuit pattern of the circuit board.

In one embodiment, the step of processing the conductive fixing member to fix the magnet between the conductive fixing member and the circuit board includes: punching the main body to form a contact portion on the main body, wherein the contact portion is configured to press the magnet, so that the magnet can be fixed between the main body, the connecting legs and the circuit board.

In one embodiment, the conductive fixing member further includes a limiting flange, one end of the limiting flange is connected to the main body, another end of the limiting flange is a free end, and the step of processing the conductive fixing member to fix the magnet between the conductive fixing member and the circuit board includes: bending the limiting flange, so that the magnet can be restricted between the main body, the connecting legs, the limiting flange and the circuit board.

In one embodiment, at least one of the connecting legs is electrically connected to the circuit pattern by welding.

In one embodiment, the manufacturing method of a magnetic electronic component further includes the following steps of: connecting a power fixing member to the circuit board, so that the power fixing member can be electrically connected to the circuit pattern of the circuit board; and disposing a battery between the power fixing member and the circuit board, so that the battery can be electrically connected to the circuit pattern of the circuit board for providing a driving power to the functional part.

As mentioned above, the magnetic electronic component of this disclosure includes a circuit board, a functional part, at least one magnet, and at least one conductive fixing member. The functional part is arranged on the circuit board and electrically connected to the circuit pattern of the circuit board. The conductive fixing member is configured to electrically connect the circuit pattern of the circuit board and fix the magnet at one side of the circuit board. Compared with the conventional art, the magnetic electronic component of this disclosure has a simple structure design, so that the magnetic electronic component can be easily manufactured, and the manufacturing cost thereof can be reduced.

In addition, the hand-made circuit kit of this disclosure includes a mounting plate, a circuit pattern module, and at least one of the above-mentioned magnetic electronic component. The circuit pattern module is arranged on the mounting plate, and the circuit pattern module includes at least one circuit line pattern. The magnetic electronic component is detachably and movably arranged on the circuit pattern module and magnetically attached on the mounting plate, so that the circuit pattern module is located between the magnetic electronic component and the mounting plate. When the magnetic electronic component is arranged on the circuit pattern module, the magnet is magnetically attached on the mounting plate, and the conductive fixing member contacts the circuit line pattern. Compared with the conventional art, the magnetic electronic component of the hand-made circuit kit of this disclosure includes a conductive fixing member capable of providing a larger electrical contact surface, which is benefit to the assembling operation of the magnetic electronic component in the hand-made circuit kit.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1 is a schematic diagram showing a conventional magnetic electrical component;

FIG. 2 is a schematic perspective diagram showing a magnetic electronic component according to an embodiment of this disclosure;

FIG. 3 is another schematic perspective diagram showing the magnetic electronic component according to the embodiment of this disclosure;

FIG. 4 is an exploded view of the magnetic electronic component according to the embodiment of this disclosure;

FIG. 5 is a schematic perspective diagram showing a magnetic electronic component according to another embodiment of this disclosure;

FIG. 6 is a schematic perspective diagram showing a hand-made circuit kit according to an embodiment of this disclosure;

FIG. 7 is a sectional view of the hand-made circuit kit according to the embodiment of this disclosure;

FIG. 8 is another sectional view of the hand-made circuit kit according to the embodiment of this disclosure;

FIGS. 9 and 10 are sectional views of the hand-made circuit kit according to different embodiments of this disclosure;

FIG. 11 is a flow chart of a manufacturing method of a magnetic electronic component according to an embodiment of this disclosure; and

FIG. 12 is a flow chart of a manufacturing method of a magnetic electronic component according to another embodiment of this disclosure.

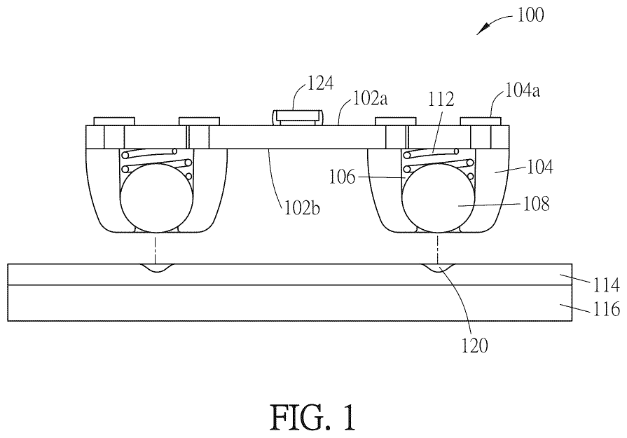

### DETAILED DESCRIPTION OF THE DISCLOSURE

The present disclosure will be apparent from the following detailed description, which proceeds with reference to the accompanying drawings, wherein the same references relate to the same elements.

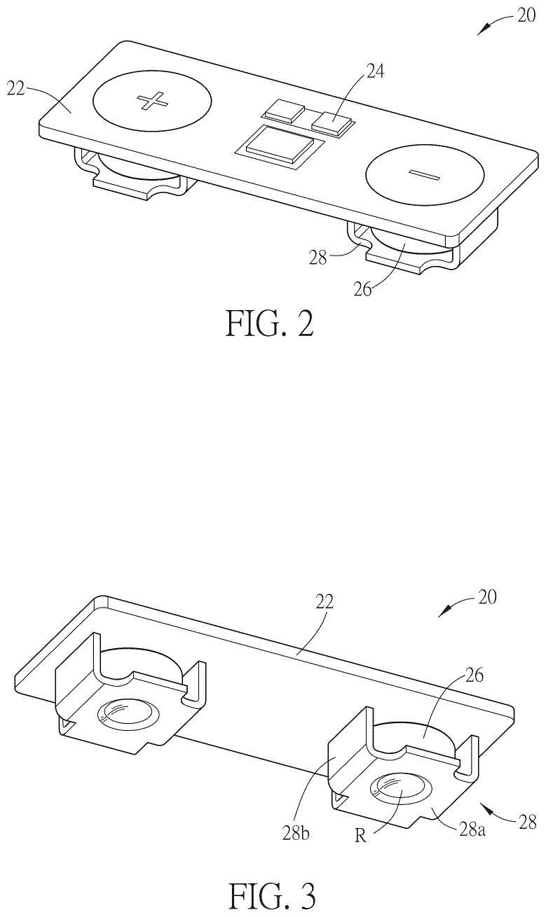

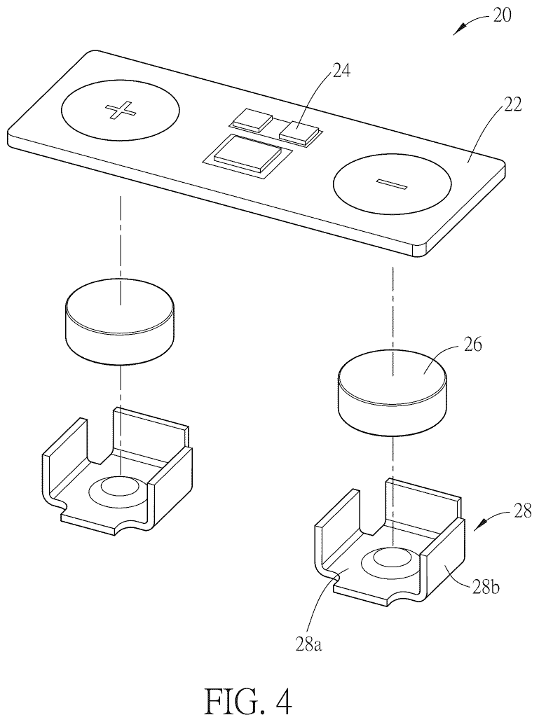

FIG. 2 is a schematic perspective diagram (upper perspective) of a magnetic electronic component 20 according to an embodiment of this disclosure, FIG. 3 is another schematic perspective diagram (lower perspective) of the magnetic electronic component 20, and FIG. 4 is an exploded view of the magnetic electronic component 20.

Referring to FIGS. 2 to 4, the magnetic electronic component 20 of this embodiment includes a circuit board 22, a functional part 24, at least one magnet 26, and at least one conductive fixing member 28.

In this embodiment, the circuit board 22 has a circuit pattern. For example, the circuit board 22 can be, for example but not limited to, a printed circuit board (PCB). The circuit board 22 may have a multi-layer structure including, for example, one or more circuit layers, each of which includes a plurality of conductive traces. A plurality of connection pads can be provided on the upper surface and the lower surface of the circuit board 22. These conductive traces and the connection pads may together define the circuit pattern of the circuit board 22. In addition, the circuit board 22 may have a plate structure of any suitable shape, such as, for example but not limited to, circle, triangle, rectangle, or polygon. In this embodiment, the circuit board 22 is, for example, a rectangular plate structure. To be noted, the above description is for an illustration only, and this disclosure is not limited thereto.

The functional part 24 is disposed on the circuit board 22 and is electrically connected to the circuit pattern of the circuit board 22. In this embodiment, the functional part 24 is disposed on the upper surface of the circuit board 22, and the functional part 24 can be, for example but not limited to, a passive part, an active part, a power supply part, a switch part, and/or a conductive part. In another case, the functional part 24 can be, for example but not limited to, a light-emitting diode, a buzzer, a speaker, a motor, a fan, a color change plate, a heater, and/or an electromagnet. In this embodiment, the functional part 24 is, for example, a light-emitting diode. Furthermore, in this embodiment, the functional part 24 may be, for example, electrically connected to the connection pad(s) on the upper surface of the circuit board 22, thereby electrically connecting the functional part 24 to the circuit pattern of the circuit board 22. To be noted, the above description is for an illustration only, and this disclosure is not limited thereto.

Referring to FIGS. 2 to 4, the magnet 26 is disposed at one side of the circuit board 22, and the conductive fixing member 28 is electrically connected to the circuit pattern of the circuit board 22 and fixes the magnet 26. The conductive fixing member 28 includes a main body 28a and at least two connecting legs 28b. In this embodiment, the conductive fixing member 28 includes three connecting legs 28b. As shown in FIGS. 2 to 4, the magnet 26 is disposed between the circuit board 22 and the main body 28a. The connecting legs 28b connect the main body 28a to the circuit board 22 and are positioned adjacent to the magnet 26, thereby restricting the magnet 26 between the main body 28a, the connecting legs 28b, and the circuit board 22. Furthermore, at least one of the connecting legs 28b is electrically connected to the circuit pattern of the circuit board 22. For example, any of the connecting legs 28b can be electrically connected to a connection pad disposed on the lower surface of the circuit board 22 by welding, thereby forming an electrical connection with the circuit pattern of the circuit board 22. Thus, the functional part 24 can be electrically connected to the conductive fixing member 28 through the circuit pattern of the circuit board 22. To be noted, the above description is for an illustration only, and this disclosure is not limited thereto.

In addition, the main body 28a can further include a contact portion R for pressing the magnet 26, so that the magnet 26 can be fixed between the main body 28a, the connecting legs 28b, and the circuit board 22.

As shown in FIGS. 2 to 4, in this embodiment, the magnetic electronic component 20 includes two magnets 26 and two conductive fixing members 28. The two conductive fixing members 28 are respectively electrically connected to the circuit pattern of the circuit board 22 and respectively fix the two magnets 26. It should be noted that the above description is for an illustration only, and this disclosure is not limited thereto. For example, in another embodiment (not shown), the magnetic electronic component 20 may include three magnets 26 and three conductive fixing members 28. The three conductive fixing members 28 are respectively electrically connected to the circuit pattern of the circuit board 22 and respectively fix the three magnets 26. In this case, the circuit board 22 of the magnetic electronic component 20 may be, for example, a triangular plate. It should be noted that if a battery is used to replace one of the magnets in this embodiment, the magnetic electronic component can actively provide power, for example, to the functional part to drive the functional part. This type of magnetic electronic component can be referred to as an active magnetic electronic component. In contrast, the magnetic electronic component 20 described above, which does not include a battery, can be referred to as a passive magnetic electronic component.

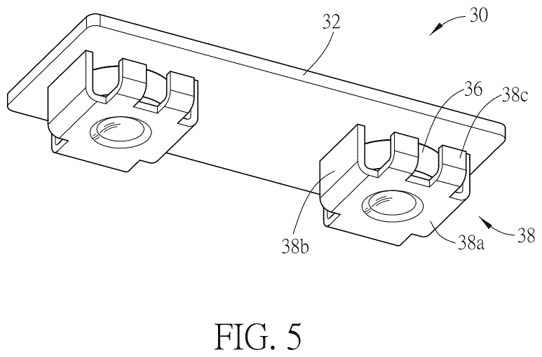

FIG. 5 is a schematic perspective diagram showing a magnetic electronic component 30 according to another embodiment of this disclosure. The component configurations and connections of the magnetic electronic component 30 of this embodiment as shown in FIG. 5 are mostly the same as those of the magnetic electronic component 20 of the previous embodiment as shown in FIG. 3. Unlike the previous embodiment, the conductive fixing member 38 of the magnetic electronic component 30 further includes a limiting flange 38c. One end of the limiting flange 38c is connected to the main body 38a, and another end of the limiting flange 38c is a free end. The limiting flange 38c is located adjacent to the magnet 36, so that the magnet 36 can be restricted between the main body 38a, the connecting legs 38b, the limiting flange 38c, and the circuit board 32. In this embodiment, the number of the limiting flanges 38c can be determined based on actual needs. For example, as shown in FIG. 5, the conductive fixing member 38 includes two limiting flanges 38c. It should be noted that the above description is for an illustration only, and this disclosure is not limited thereto. For example, in one embodiment, the conductive fixing member may include two connecting legs and two sets of limiting flanges, and the connecting legs and the limiting flanges are alternately arranged around the main body, wherein each set of limiting flanges may include one or two limiting flanges (not shown).

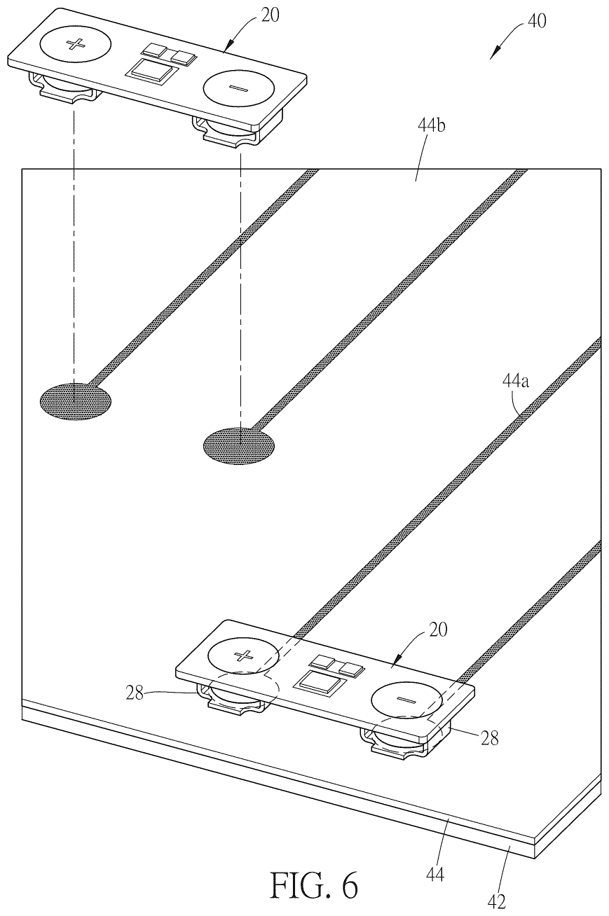

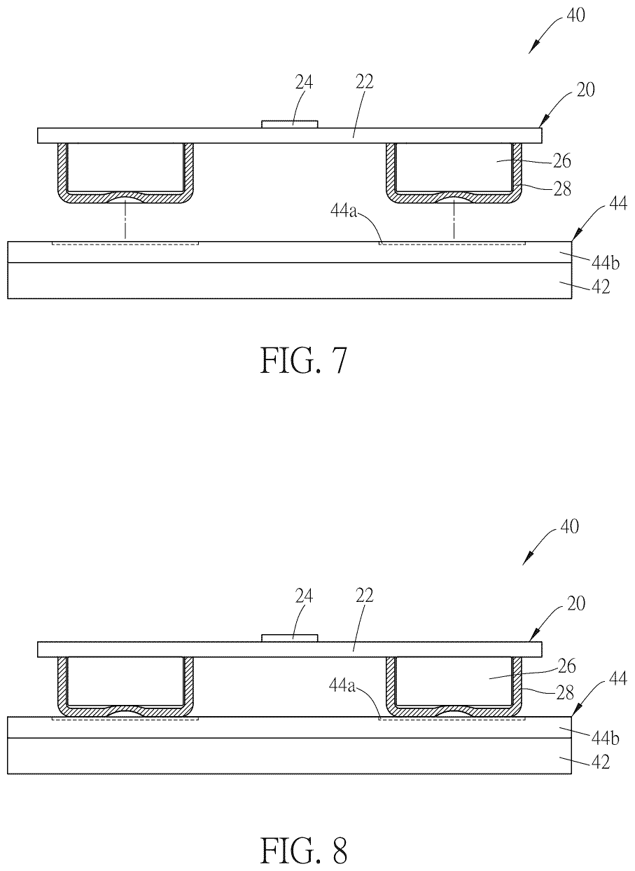

A hand-made circuit kit 40 according to an embodiment of this disclosure will be described hereinafter with reference to FIGS. 6 to 8, wherein FIG. 6 is a schematic perspective diagram of the hand-made circuit kit 40, FIG. 7 is a sectional view of the hand-made circuit kit 40, and FIG. 8 is another sectional view of the hand-made circuit kit 40.

Referring to FIGS. 6 to 8, the hand-made circuit kit 40 of this embodiment includes a mounting plate 42, a circuit pattern module 44, and at least one magnetic electronic component 20. In this embodiment, the hand-made circuit kit 40 may include, for example, a plurality of the above-mentioned magnetic electronic components 20, and the structure and design thereof can be referred to the above embodiment, so the detailed descriptions thereof will be omitted here. To be noted, in other embodiments, the hand-made circuit kit 40 may include a plurality of the above-mentioned magnetic electronic components 30, or a plurality of the magnetic electronic components 20 and 30, and this disclosure is not limited thereto.

In this embodiment, the circuit pattern module 44 is arranged on the mounting plate 42, and the circuit pattern module 44 includes at least one circuit line pattern 44a. The magnetic electronic component 20 is detachably and movably arranged on the circuit pattern module 44 and magnetically attached on the mounting plate 42, so that the circuit pattern module 44 can be located between the magnetic electronic component(s) 20 and the mounting plate 42. When the magnetic electronic component 20 is arranged on the circuit pattern module 44, the magnet 26 of the magnetic electronic component 20 can be magnetically attached on the mounting plate 42, and the conductive fixing member 28 of the magnetic electronic component 20 can contact the circuit line pattern 44a.

In this embodiment, the mounting plate 42 can be, for example but not limited to, an iron plate, so that the magnet 26 can be attached to the mounting plate 42 by magnetic attraction. In addition, the handmade circuit module 44 may further include a substrate 44b, and the circuit line pattern 44a is arranged on the substrate 44b. In this case, the circuit line pattern 44a can be formed by, for example but not limited to, at least one of a conductive sticker, a conductive ink, a conductive paste, and a conductive paper, and the substrate 44b can be, for example but not limited to, a rigid substrate or a flexible substrate, such as a paper card or a plastic card. As mentioned above, in this embodiment, the conductive stickers can be attached to the substrate 44b based on a proper design so as to form the circuit line pattern 44a on the substrate 44b. In another embodiment, a conductive ink pen can be used to draw directly on the substrate 44b, and the drawn pattern (conductive ink) can define the circuit line pattern 44a on the substrate 44b. To be noted, the above description is for an illustration only, and this disclosure is not limited thereto.

In other embodiments, the handmade circuit module 44 can be formed without the substrate 44b. For example, the conductive stickers can be directly attached to the mounting plate 42 according to a proper design to form the circuit line pattern 44a on the mounting plate 42 directly. In another embodiment, the conductive ink pen can be used to draw directly on the mounting plate 42, and the drawn pattern can define the circuit line pattern 44a on the mounting plate 42. To be noted, the above description is for an illustration only, and this disclosure is not limited thereto.

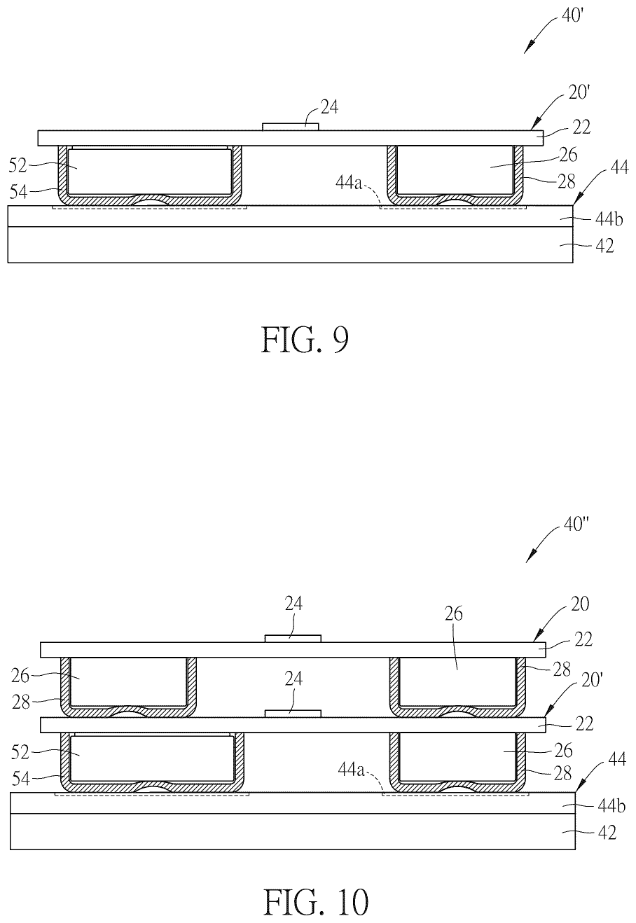

FIG. 9 is a sectional view of the hand-made circuit kit 40′ according to another embodiment of this disclosure.

The component configurations and connections of the hand-made circuit kit 40′ of this embodiment as shown in FIG. 9 are mostly the same as those of the hand-made circuit kit 40 of the aforementioned embodiment. Unlike the previous embodiment, the magnetic electronic component 20′ of the hand-made circuit kit 40′ of this embodiment includes a combination of a magnet 26 and a conductive fixing member 28 and a combination of a battery 52 and a power fixing member 54. In this embodiment, the battery 52 is electrically connected to the circuit pattern of the circuit board 22 to provide driving power to the functional part 24. The power fixing member 54 is configured to electrically connect to the circuit pattern of the circuit board 22 and fix the battery 52. The battery 52 can be, for example but not limited to, a button battery. When the power fixing member 54 is connected to the circuit board 22, the battery 52 can be fixed between the power fixing member 54 and the circuit board 22. In particular, the battery 52 can be removably disposed between the power fixing member 54 and the circuit board 22, so that it can be replaced when the battery 52 is depleted. Moreover, when the magnetic electronic component 20′ is arranged on the circuit pattern module 44, the power fixing member 54 is in contact with the circuit line pattern 44a, so the circuit line pattern 44a and the circuit pattern of the circuit board 22 can be electrically connected through the power fixing member 54. It should be noted that the power fixing member 54 and the battery 52 can be designed to be electrically isolated from each other, so that the battery 52 is not directly electrically connected to the circuit line pattern 44a through the power fixing member 54. In one embodiment, an insulating layer can be formed on the inner side of the power fixing member 54, so that the power fixing member 54 and the battery 52 are electrically insulated from each other. In this embodiment, since the magnetic electronic component 20′ itself is provided with a battery 52 to provide the driving power to the functional part 24, the magnetic electronic component 20′ can be realized as an active magnetic electronic component.

To be noted, the configurations and connections of other elements in this embodiment can refer to the above embodiments, so the detailed descriptions thereof will be omitted. The above description is for an illustration only, and this disclosure is not limited thereto.

FIG. 10 is a sectional view of the hand-made circuit kit 40″ according to another embodiment of this disclosure.

The component configurations and connections of the hand-made circuit kit 40″ of this embodiment as shown in FIG. 10 are mostly the same as those of the hand-made circuit kit 40′ of the previous embodiment. Unlike the previous embodiment, the hand-made circuit kit 40″ of this embodiment further includes a magnetic electronic component 20, which can be directly stacked on a magnetic electronic component 20′, and the magnetic electronic component 20′ is directly disposed on the circuit pattern module 44. In this embodiment, the battery 52 of the magnetic electronic component 20′ can be used to simultaneously provide the driving power to the functional part 24 of the magnetic electronic component 20′ and the functional part 24 of the magnetic electronic component 20. In this embodiment, the magnetic electronic component 20′ can be referred to as an active magnetic electronic component, while the magnetic electronic component 20 can be referred to as a passive magnetic electronic component. Therefore, the hand-made circuit kit 40″ of this embodiment implements a design that combines active and passive magnetic electronic components.

To be noted, the configurations and connections of other elements in this embodiment can refer to the above embodiments, so the detailed descriptions thereof will be omitted. The above description is for an illustration only, and this disclosure is not limited thereto.

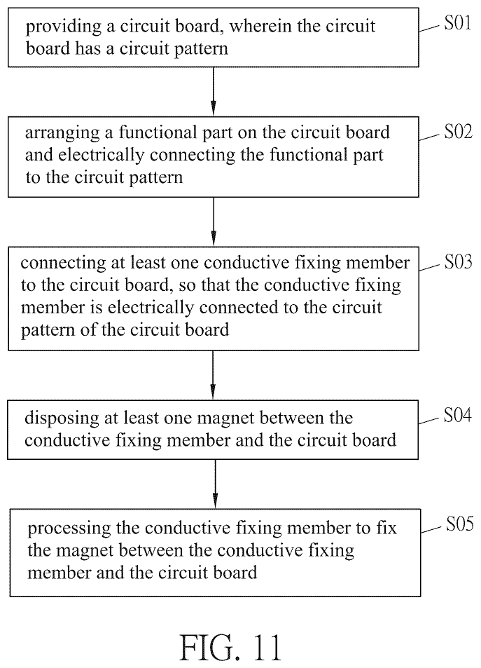

FIG. 11 is a flow chart of a manufacturing method of a magnetic electronic component according to an embodiment of this disclosure.

As shown in FIG. 11, the manufacturing method of a magnetic electronic component includes the following steps of: providing a circuit board, wherein the circuit board has a circuit pattern (step S01); arranging a functional part on the circuit board and electrically connecting the functional part to the circuit pattern (step S02); connecting at least one conductive fixing member to the circuit board, so that the conductive fixing member is electrically connected to the circuit pattern of the circuit board (step S03); disposing at least one magnet between the conductive fixing member and the circuit board (step S04); and processing the conductive fixing member to fix the magnet between the conductive fixing member and the circuit board (step S05).

In this embodiment, the step of connecting at least one conductive fixing member to the circuit board (step S03) includes: connecting the connecting legs to the circuit board, and electrically connecting at least one of the connecting legs to the circuit pattern of the circuit board. In this embodiment, at least one of the connecting legs is electrically connected to the circuit pattern by welding.

In addition, the step of processing the conductive fixing member to fix the magnet between the conductive fixing member and the circuit board (step S05) includes: punching the main body to form a contact portion on the main body, wherein the contact portion is configured to press the magnet, so that the magnet can be fixed between the main body, the connecting legs and the circuit board.

In addition, the step of processing the conductive fixing member to fix the magnet between the conductive fixing member and the circuit board (step S05) includes: bending the limiting flange, so that the magnet can be restricted between the main body, the connecting legs, the limiting flange and the circuit board.

To be noted, the configurations and connections of other elements in this embodiment can refer to the above embodiments, so the detailed descriptions thereof will be omitted. The above description is for an illustration only, and this disclosure is not limited thereto.

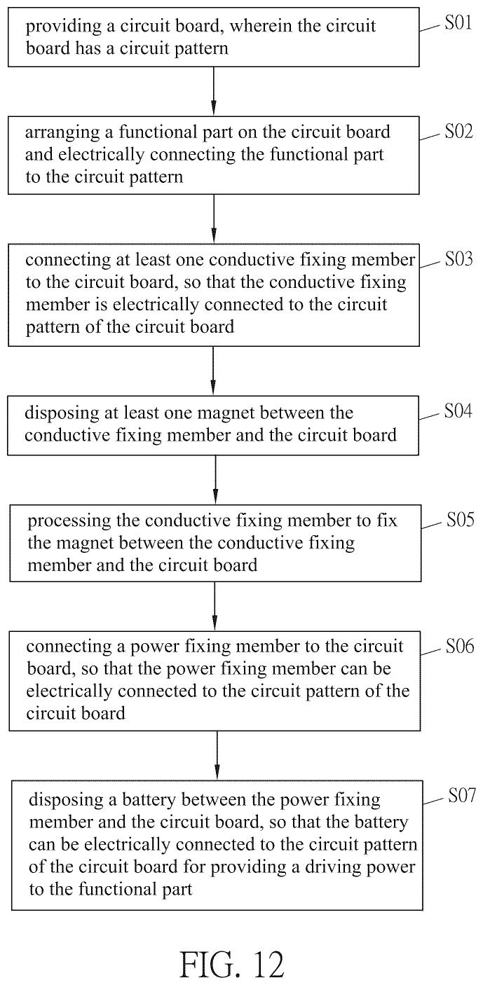

FIG. 12 is a flow chart of a manufacturing method of a magnetic electronic component according to another embodiment of this disclosure.

The steps of the manufacturing method of a magnetic electronic component of this embodiment as shown in FIG. 12 are mostly the same as those of the manufacturing method of the previous embodiment as shown in FIG. 11. The difference therebetween is that the manufacturing method of this embodiment further includes the following steps of: connecting a power fixing member to the circuit board, so that the power fixing member can be electrically connected to the circuit pattern of the circuit board (step S06); and disposing a battery between the power fixing member and the circuit board, so that the battery can be electrically connected to the circuit pattern of the circuit board for providing a driving power to the functional part (step S07).

To be noted, the configurations and connections of other elements in this embodiment can refer to the above embodiments, so the detailed descriptions thereof will be omitted. The above description is for an illustration only, and this disclosure is not limited thereto.

In summary, the magnetic electronic component of this disclosure includes a circuit board, a functional part, at least one magnet, and at least one conductive fixing member. The functional part is arranged on the circuit board and electrically connected to the circuit pattern of the circuit board. The conductive fixing member is configured to electrically connect the circuit pattern of the circuit board and fix the magnet at one side of the circuit board. Compared with the conventional art, the magnetic electronic component of this disclosure has a simple structure design, so that the magnetic electronic component can be easily manufactured, and the manufacturing cost thereof can be reduced.

In addition, the hand-made circuit kit of this disclosure includes a mounting plate, a circuit pattern module, and at least one of the above-mentioned magnetic electronic component. The circuit pattern module is arranged on the mounting plate, and the circuit pattern module includes at least one circuit line pattern. The magnetic electronic component is detachably and movably arranged on the circuit pattern module and magnetically attached on the mounting plate, so that the circuit pattern module is located between the magnetic electronic component and the mounting plate. When the magnetic electronic component is arranged on the circuit pattern module, the magnet is magnetically attached on the mounting plate, and the conductive fixing member contacts the circuit line pattern. Compared with the conventional art, the magnetic electronic component of the hand-made circuit kit of this disclosure includes a conductive fixing member capable of providing a larger electrical contact surface, which is benefit to the assembling operation of the magnetic electronic component in the hand-made circuit kit.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. A magnetic electronic component, comprising:
a circuit board having a circuit pattern;
a functional part arranged on the circuit board and electrically connected to the circuit pattern;
at least one magnet located at one side of the circuit board; and
at least one conductive fixing member configured to electrically connect the circuit pattern of the circuit board and fix the magnet.

2. The magnetic electronic component of claim 1, wherein the conductive fixing member comprises a main body and at least two connecting legs, the magnet is disposed between the circuit board and the main body, each of the connecting legs connects the main body and the circuit board and located adjacent to the magnet so as to limit the magnet between the main body, the connecting legs and the circuit board, and at least one of the connecting legs is electrically connected to the circuit pattern of the circuit board.

3. The magnetic electronic component of claim 2, wherein the conductive fixing member further comprises a limiting flange, one end of the limiting flange is connected to the main body, another end of the limiting flange is a free end, and the limiting flange is located adjacent to the magnet, so that the magnet is restricted between the main body, the connecting legs, the limiting flange and the circuit board.

4. The magnetic electronic component of claim 2, wherein at least one of the connecting legs is electrically connected to the circuit pattern by welding.

5. The magnetic electronic component of claim 1, wherein the circuit board is a printed circuit board, and the circuit pattern comprises at least one conductive line formed on the printed circuit board.

6. The magnetic electronic component of claim 1, wherein the functional part is electrically connected to the conductive fixing member through the circuit pattern.

7. The magnetic electronic component of claim 1, wherein the functional part comprises a passive part, an active part, a power supply part, a switch part, a conductive part, a light-emitting diode, a buzzer, a speaker, a motor, a fan, a color change plate, a heater, and/or an electromagnet.

8. The magnetic electronic component of claim 1, wherein the magnetic electronic component comprises two of the magnets and two of the conductive fixing members, and the two conductive fixing members are electrically connected to the circuit pattern of the circuit board and fix the two magnets, respectively.

9. The magnetic electronic component of claim 1, further comprising:
a battery electrically connected to the circuit pattern of the circuit board for providing a driving power to the functional part; and
a power fixing member configured to electrically connect the circuit pattern of the circuit board and fix the battery.

10. A hand-made circuit kit, comprising:
a mounting plate;
a circuit pattern module arranged on the mounting plate, wherein the circuit pattern module comprises at least one circuit line pattern; and
a magnetic electronic component detachably and movably arranged on the circuit pattern module and magnetically attached on the mounting plate, so that the circuit pattern module is located between the magnetic electronic component and the mounting plate, wherein the magnetic electronic component comprises:
a circuit board having a circuit pattern,
a functional part arranged on the circuit board and electrically connected to the circuit pattern,
at least one magnet located at one side of the circuit board, and
at least one conductive fixing member configured to electrically connect the circuit pattern of the circuit board and fix the magnet;
wherein, when the magnetic electronic component is arranged on the circuit pattern module, the magnet is magnetically attached on the mounting plate, and the conductive fixing member contacts the circuit line pattern.

11. The hand-made circuit kit of claim 10, wherein the conductive fixing member comprises a main body and at least two connecting legs, the magnet is disposed between the circuit board and the main body, each of the connecting legs connects the main body and the circuit board and located adjacent to the magnet so as to limit the magnet between the main body, the connecting legs and the circuit board, and at least one of the connecting legs is electrically connected to the circuit pattern of the circuit board.

12. The hand-made circuit kit of claim 11, wherein the conductive fixing member further comprises a limiting flange, one end of the limiting flange is connected to the main body, another end of the limiting flange is a free end, and the limiting flange is located adjacent to the magnet, so that the magnet is restricted between the main body, the connecting legs, the limiting flange and the circuit board.

13. The hand-made circuit kit of claim 11, wherein at least one of the connecting legs is electrically connected to the circuit pattern by welding.

14. The hand-made circuit kit of claim 10, wherein the functional part is electrically connected to the conductive fixing member through the circuit pattern.

15. The hand-made circuit kit of claim 10, wherein the circuit pattern module further comprises a substrate, and the circuit line pattern is arranged on the substrate.

16. The hand-made circuit kit of claim 10, wherein the circuit line pattern is formed by at least one of a conductive sticker, a conductive ink, a conductive paste, and a conductive paper.

17. The hand-made circuit kit of claim 10, wherein the magnetic electronic component further comprises:
a battery electrically connected to the circuit pattern of the circuit board for providing a driving power to the functional part; and
a power fixing member configured to electrically connect the circuit pattern of the circuit board and fix the battery;
wherein, when the magnetic electronic component is arranged on the circuit pattern module, the power fixing member contacts the circuit line pattern.
